(19) United States
(12) Patent Application Publication
(10) Pub. No.: US 2009/0026492 A1
(43) Pub. Date: Jan. 29, 2009

(54) LATERAL JUNCTION BREAKDOWN TRIGGERED SILICON CONTROLLED RECTIFIER BASED ELECTROSTATIC DISCHARGE PROTECTION DEVICE

(76) Inventors: Kiran V. Chatty, Williston, VT (US); Robert J. Gauthier, JR., Hinesburg, VT (US); Dimitrios K. Kontos, San Jose, CA (US); Mujahid Muhammad, Essex Junction, VT (US)

Correspondence Address: SCULLY, SCOTT, MURPHY & PRESSER, P.C., 400 GARDEN CITY PLAZA, Suite 300, GARDEN CITY, NY, 11530, US

(21) Appl. No.: 11/782,800

(22) Filed: Jul. 25, 2007

(51) Int. Cl. H01L 29/72

(52) U.S. Cl. 257/173; 257/E29.181

(57) ABSTRACT

The components of a silicon controlled rectifier, which are a p-doped anode, an n-well middle region, a p-well middle region, and an n-doped cathode, are formed along sidewalls and a bottom surface of a shallow trench isolation structure. The p-doped anode and the n-doped cathode are formed directly underneath a top surface of a silicon substrate. A trigger mechanism that provides an instantaneous turn-on current to latch the silicon controlled rectifier to an on-state is also provided. The trigger mechanism provides a temporary surge in the voltage of the p-doped middle region, causing the instantaneous turn-on current to flow from the p-doped middle region to the n-doped cathode. Combined with the proximity of the p-doped anode to the n-doped cathode, the trigger mechanism provides a fast turn on and a short low resistance current path for the electrostatic discharge protection circuit.

### FIELD OF THE INVENTION

The present invention relates to a semiconductor structures, and particularly to semiconductor structures for an electrostatic discharge protection circuit that employs a lateral junction breakdown triggered silicon controlled rectifier.

### BACKGROUND OF THE INVENTION

An electrostatic discharge (ESD) event can occur in a semiconductor chip when a charged conductor (including the human body) discharges through the semiconductor chip. Three models for ESD events are widely accepted in the semiconductor industry: Human Body Model (HBM), Machine Model (MM), and Charged Device Model (CDM).

An electrostatic charge may accumulate on a human body, for example, when he walks on a carpet. Contact of a body part, e.g., a finger, to a device containing a semiconductor chip causes the body to discharge, possibly causing damage to the semiconductor device. The model used to simulate this event is the Human Body Model (HBM). A similar discharge may occur from a charged conductive object, such as a metallic tool. The model used to characterize this event is known as the Machine Model (MM). Static charge may accumulate on a semiconductor chip through handling or contact with packaging materials or work surfaces. The model used to simulate the transfer of charge from a charged device to another object is referred to as the Charged Device Model (CDM). The CDM employs an energy source that can discharge through its lead into another device of different potential. Often, the rise time is less than 0.5 ns, and the duration can be less than 2 ns.

As electronic devices scale down in each successive generation of semiconductor technology, the thickness of gate oxide decreases, which results in reduction of gate oxide breakdown voltage and makes semiconductor devices more vulnerable to electrostatic discharge events. Further, the cross-sectional area of metal wiring lines decreases, resulting in an increase in power bus resistance.

The reduction in the current carrying capabilities is more prominent in a positive power supply network, or the Vdd network. A diode based electrostatic discharge protection circuit, which utilizes the positive power supply network, becomes less effective in protecting semiconductor devices with the scaling of semiconductor devices as the current carrying capabilities of an electrostatic discharge protection circuit are limited by the increased power bus resistance. Typically, a ground network has more robust wiring having a lower bus resistance than the positive power supply network.

Silicon controlled rectifier (SCR) based electrostatic discharge protection circuit employs only the ground network to conduct electrostatic discharge current. Since the positive power supply network is not used to conduct an electrostatic discharge current, SCR based electrostatic discharge protection circuit offers an advantage over diode based electrostatic discharge protection circuits in terms of the capability to conduct a large amount of current.

FIG. 1A shows a physical structure of a silicon controlled rectifier (SCR), which comprises a stack of a p-doped anode 10, an n-doped middle region 20, a p-doped middle region 30, and an n-doped cathode 40. An anode lead wire 12 is connected to the p-doped anode 10, a cathode lead wire 42 is connected to the n-doped cathode 42, a first gate lead wire 32 may optionally be connected to the p-doped middle region 30, and a second gate lead wire 33 may optionally be connected to the n-doped middle region 20. FIG. 1B shows an equivalent circuit schematic for the SCR in FIG. 1A, wherein the physical structure of the SCR in FIG. 1A is represented by a PNP bipolar transistor and an NPN bipolar transistor.

Referring to FIG. 2, a prior art SCR based electrostatic discharge protection circuit formed in a silicon substrate 8 comprises a p-doped anode 10, an n-well middle region 20′, a heavily n-doped middle region 20″, a p-well middle region 30′, an n-doped cathode 40, and a gate electrode 36 on a gate dielectric 34, which is located on the p-well middle region 30′. The n-well middle region 20′, and the heavily n-doped middle region 20″ collectively comprise an n-doped middle region 20. The p-well middle region 30′ is also a p-doped middle region 30. A p-doped middle region contact 31 comprises a heavily p-doped silicon material. The portion of the silicon substrate 8 that is located beneath the n-well middle region 20′ and the p-well middle region 30′ comprises the substrate layer 2, which has the original doping level of the silicon substrate 8. Shallow trench isolation (STI) 50 separates the p-doped anode 10 and the heavily n-doped middle region 20″. The STI 50 also separates the n-doped cathode 40 and the p-doped middle region contact 31.

An input/output pad (I/O pad) 100, to which electrostatic discharge protection is provided, is connected to the p-doped cathode 10. The n-doped cathode 40 is connected to ground. The p-doped middle region contact 31 and the gate electrode 36 are also connected to the ground. During an electrostatic discharge event, the voltage of the heavily n-doped middle region 20″ rises instantaneously, causing an instantaneous current to flow through the device formed by the heavily n-doped middle region 20″, the p-well middle region 30′, and the n-doped cathode 40. The instantaneous current causes the SCR to latch on to the on-state. The SCR remains turned on until the current decreased to a low-current dropout level. Thus, the prior art SCR based electrostatic discharge (ESD) protection circuit passes current during an electrostatic discharge event.

The efficiency of the prior art SCR based ESD protection circuit depends on the dimension of the physical components of the SCR, especially on the dimension between the p-doped anode 10 and the n-doped cathode 40. Referring to FIG. 3, a graph showing the dependence of the turn-on time, i.e., the time needed for the prior art SCR circuit to turn on after an ESD event, is plotted as a function of the spacing S_{ac} between the p-doped anode 10 and the n-doped cathode 40. For an SCR based ESD protection circuit to turn on with minimal delay from an ESD event, the dimension between the p-doped anode 10 and the n-doped cathode 40 needs to be minimized.

Therefore, there exists a need for an effective SCR based ESD protection circuit having a small turn-on delay time and low critical rate of voltage rise.

Further, there exists a need for an SCR based ESD protection circuit having a small dimension between a p-doped anode and an n-doped cathode.

### SUMMARY OF THE INVENTION

The present invention addresses the needs described above by providing silicon controlled rectifier based electrostatic discharge protection structures having a small dimension between a p-doped anode and an n-doped cathode.

Specifically, the components of a silicon controlled rectifier, which are a p-doped anode, an n-well middle region, a p-well middle region, and an n-doped cathode, are formed along sidewalls and a bottom surface of a shallow trench isolation structure. The p-doped anode and the n-doped cathode are formed directly underneath a top surface of a silicon substrate. A trigger mechanism that provides an instantaneous turn-on current to latch the silicon controlled rectifier to an on-state is also provided. The trigger mechanism provides a temporary surge in the voltage of the p-doped middle region, causing the instantaneous turn-on current to flow from the p-doped middle region to the n-doped cathode. Combined with the proximity of the p-doped anode to the n-doped cathode, the trigger mechanism provides a fast turn on and a short low resistance current path for the electrostatic discharge protection circuit.

According to a first embodiment of the present invention, a semiconductor structure comprises:

a shallow trench isolation structure containing a bottom surface having a width, a first sidewall, and a second sidewall and located in a semiconductor substrate, wherein the bottom surface adjoins the first sidewall and the second sidewall;

a p-doped anode located directly beneath a top surface of the semiconductor substrate and abutting the first sidewall;

an n-well middle region abutting the p-doped anode, the first sidewall, and the bottom surface;

a p-well middle region abutting the n-well middle region, the bottom surface, and the second sidewall;

an n-doped cathode located directly beneath the top surface of the semiconductor substrate and abutting the p-well middle region and the second sidewall, wherein the p-doped anode and the n-doped cathode are separated by a distance that is substantially the same as the width of the bottom surface; and

a heavily n-doped middle region disjoined from the first sidewall, the second sidewall, the p-doped anode, and the n-doped cathode and abutting the n-well middle region and the p-well middle region, wherein the p-doped anode is wired to an input/output pad by a first metal wiring and the n-doped cathode is wired to ground by a second metal wiring.

According to a second embodiment of the present invention, a semiconductor structure comprises:

a shallow trench isolation structure containing a bottom surface having a width, a first sidewall, and a second sidewall and located in a semiconductor substrate, wherein the bottom surface adjoins the first sidewall and the second sidewall;

a p-doped anode located directly beneath a top surface of the semiconductor substrate and abutting the first sidewall;

an n-well middle region abutting the p-doped anode, the first sidewall, and the bottom surface;
a p-well middle region abutting the n-well middle region, the bottom surface, and the second sidewall;

an n-doped cathode located directly beneath the top surface of the semiconductor substrate and abutting the p-well middle region and the second sidewall, wherein the p-doped anode and the n-doped cathode are separated by a distance that is substantially the same as the width of the bottom surface; and

a heavily n-doped electrostatic discharge (ESD) trigger region located within the semiconductor substrate, electrically connected to the p-well middle region, and disjoined from the first sidewall, the second sidewall, the p-doped anode, the n-doped cathode, and the n-well middle region, wherein the p-doped anode and the heavily n-doped ESD trigger region are wired to an input/output pad by a first metal wiring and the n-doped cathode is wired to ground by a second metal wiring.

The semiconductor structure may further comprise a p-doped middle region contact containing a heavily p-doped semiconductor and wired to the ground by the second metal wiring.

The heavily n-doped ESD trigger region may abut the p-well middle region. Alternatively, the semiconductor structure may further comprise a p-doped electrostatic discharge (ESD) implantation region which abuts the heavily n-doped ESD trigger region and the p-well middle region, and is disjoined from the n-well middle region and the n-doped cathode.

According to a third embodiment of the present invention, a semiconductor structure comprises:
a shallow trench isolation structure containing a bottom surface having a width, a first sidewall, and a second sidewall and located in a semiconductor substrate, wherein the bottom surface adjoins the first sidewall and the second sidewall;

a p-doped anode located directly beneath a top surface of the semiconductor substrate and abutting the first sidewall;
an n-well middle region abutting the p-doped anode, the first sidewall, and the bottom surface;

a p-well middle region abutting the n-well middle region, the bottom surface, the second sidewall, and the top surface of the semiconductor substrate;

an n-doped cathode located directly beneath the top surface of the semiconductor substrate and abutting the p-well middle region and the second sidewall, wherein the p-doped anode and the n-doped cathode are separated by a distance that is substantially the same as the width of the bottom surface;
a heavily n-doped electrostatic discharge (ESD) trigger region located within the semiconductor substrate, abutting the p-well middle region, and disjoined from the first sidewall, the second sidewall, the p-doped anode, the n-doped cathode, and the n-well middle region; and

a gate located on the top surface of the semiconductor substrate, abutting the p-well middle region, and containing a gate dielectric and a gate conductor, wherein the p-doped anode and the heavily n-doped ESD trigger region are wired to an input/output pad by a first metal wiring and the n-doped cathode is wired to ground by a second metal wiring.

### BRIEF DESCRIPTION OF THE DRAWINGS

FIG. 1A is a schematic diagram of a prior art physical structure of a silicon controlled rectifier (SCR). FIG. 1B is an equivalent circuit schematic for the SCR in FIG. 1A.

FIG. 2 is a prior art electrostatic discharge (ESD) protection structure employing an SCR.

FIG. 3 is a graph showing the dependence of turn-on time on the spacing S_{ac} between an anode and a cathode of an SCR.

FIGS. 4A-4E show a first exemplary structure according to a first embodiment of the present invention. FIG. 4A is a top-down view, FIGS. 4B and 4C are vertical cross-sectional views along the planes B-B′ and C-C′, respectively, and FIGS. 4D, and 4E are horizontal cross-sectional views along the planes D-D′ and E-E′.

FIG. 5 is a horizontal cross-sectional views along the planes E-E′ of the first exemplary structure with annotations for geometrical aspects of the first exemplary structure and exemplary equipotential lines at an initial phase of an ESD event.

FIGS. 6A-6F show a second exemplary structure according to a first embodiment of the present invention. FIG. 6A is a top-down view, FIGS. 6B, 6C, and 6F are vertical cross-sectional views along the planes B-B′, C-C′, and F-F′, respectively, and FIGS. 6D and 6E are horizontal cross-sectional views along the planes D-D′ and E-E′.

FIG. 7 is a top down views of the second exemplary structure showing a set of vertical planes PQ, QR, and RS that are used to generate a composite vertical cross-sectional view of the second exemplary structure in FIG. 8.

FIG. 8 is a composite vertical cross-sectional view of the second exemplary structure along the set of planes PQ, QR, and RS in FIG. 7.

FIG. 9 is a composite vertical cross-sectional view of the second exemplary structure along the set of planes PQ, QR, and RS in FIG. 7 with an alternate wiring of terminals.

FIGS. 10-13 are vertical cross-sectional views of a third, fourth, fifth, and sixth exemplary structures, respectively, according to a second embodiment of the present invention.

FIGS. 14-17 are vertical cross-sectional views of a seventh, eighth, ninth, and tenth exemplary structures, respectively, according to a third embodiment of the present invention.

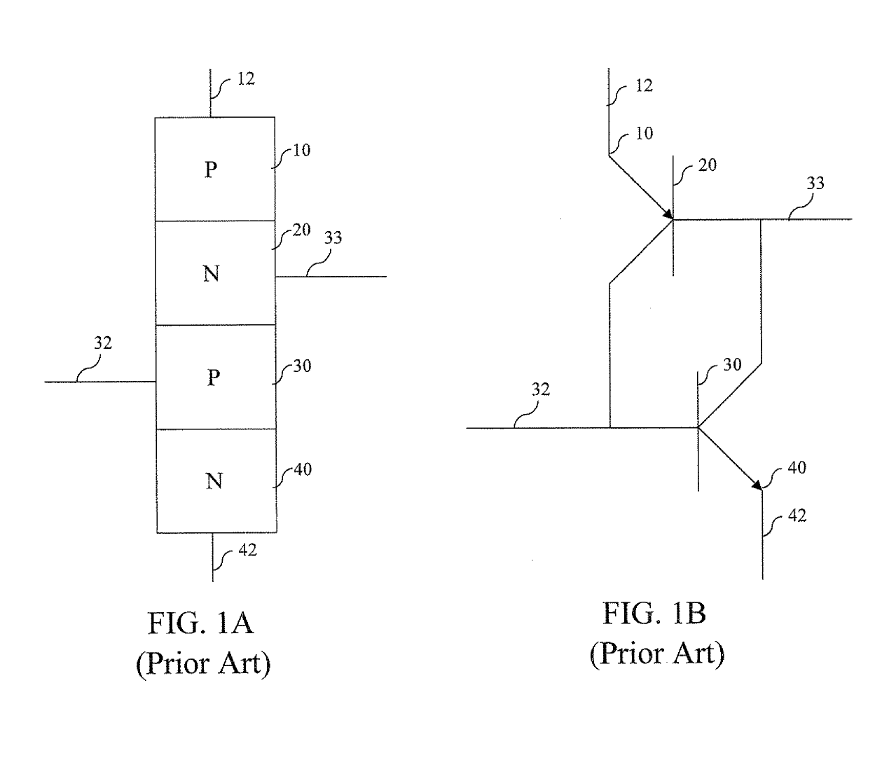

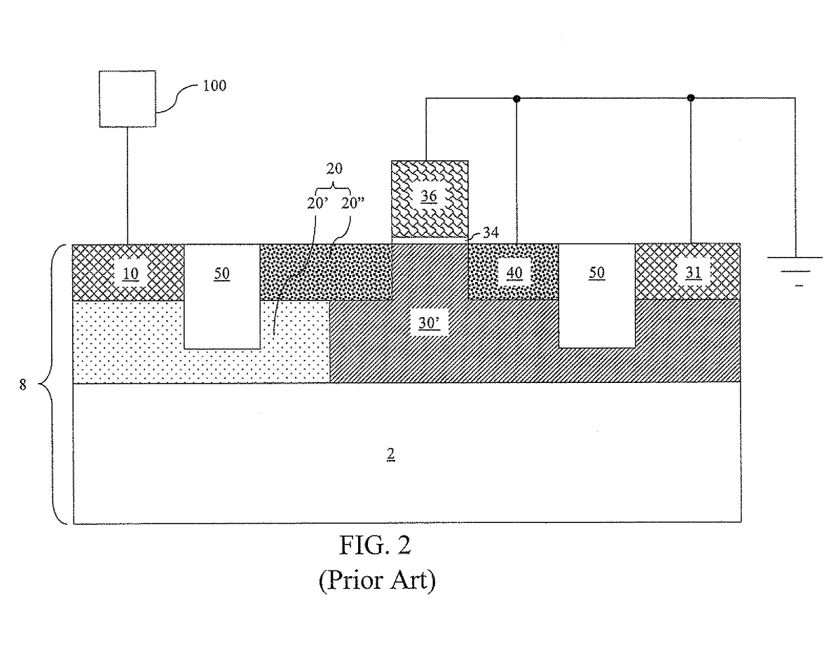

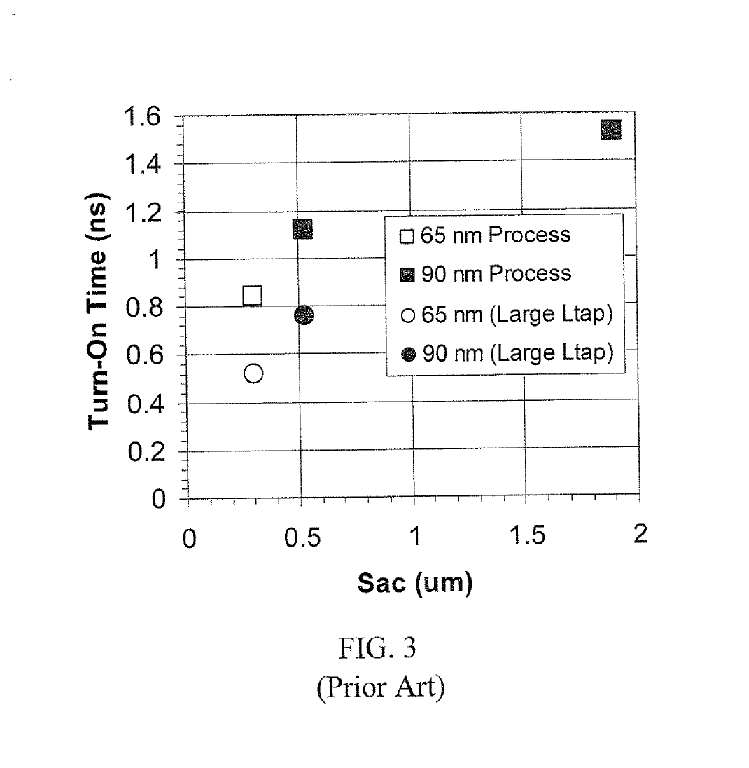

### DETAILED DESCRIPTION OF THE INVENTION

As stated above, the present invention relates to semiconductor structures for an electrostatic discharge protection circuit that employs a lateral junction breakdown triggered silicon controlled rectifier, which are now described in detail with accompanying figures. It is noted that like and corresponding elements are referred to by like reference numerals.

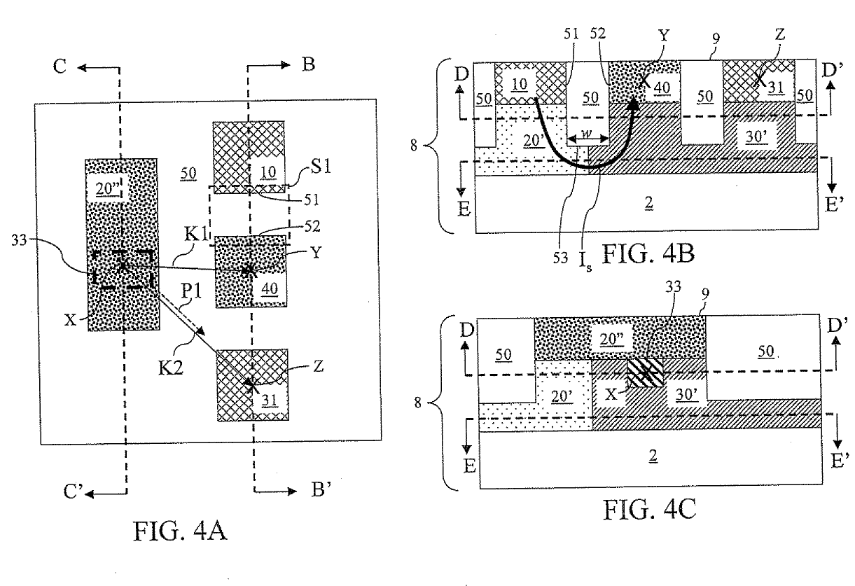

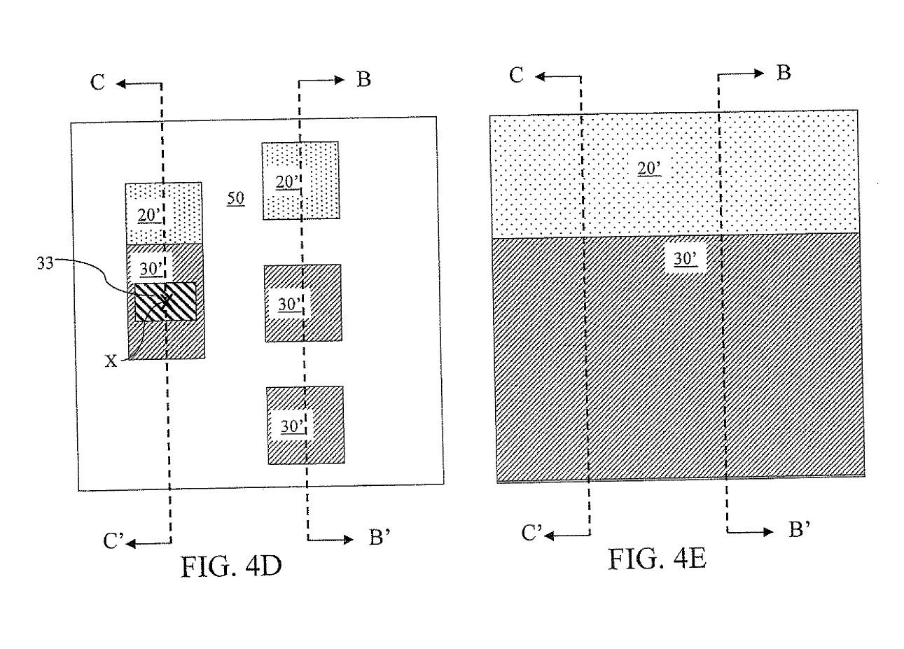

Referring to FIGS. 4A-4E, a first exemplary structure according to a first embodiment of the present invention comprises shallow trench isolation 50, a p-doped anode 10, an n-well middle region 20′, a p-well middle region 30′, an n-doped cathode 40, a heavily n-doped middle region 20″, and a substrate layer 2, each of which is located in a semiconductor substrate 8. Preferably, the first exemplary structure further comprises a p-doped middle region contact 31 as well. Each of the p-doped anode 10, the heavily n-doped middle region 20″, the n-doped cathode 40, and the p-doped middle region contact 31 comprises a doped semiconductor material and is located on a top surface 9 of the semiconductor substrate 8.

A portion S1 of the shallow trench isolation 50 is located between the p-doped anode 10 ad the n-doped cathode 40. The portion S1 of the shallow trench isolation 50 has a bottom surface 53 having a width w, a first sidewall 51, and a second sidewall 52 and located in the semiconductor substrate 8. The first sidewall 51 and the second sidewall 52 are substantially vertical. The bottom surface 53 adjoins the first sidewall 51 and the second sidewall 52.

The p-doped anode 10 is located directly beneath the top surface 9 of the semiconductor substrate 8 and abuts the first sidewall 51. The n-well middle region 20′ abuts the p-doped anode 10, the first sidewall 51, and the bottom surface 53 of the portion S1 of the shallow trench isolation 50. The p-well middle region 30′ abuts the n-well middle region 20′, the bottom surface 53, and the second sidewall 52. The n-doped cathode 40 is located directly beneath the top surface 9 of the semiconductor substrate 8 and abuts the p-well middle region 30′ and the second sidewall 52. The p-doped anode 10 and the n-doped cathode 40 are separated by a distance that is substantially the same as the width of w of the bottom surface 53. The heavily n-doped middle region 20″ is disjoined from the first sidewall 51, the second sidewall 52, the p-doped anode 10, and the n-doped cathode 40. The heavily n-doped middle region 20″ abuts the n-well middle region 20′ and the p-well middle region 30′. The n-well middle region 20′ and the p-well middle region 30′ abut the substrate layer 2.

A silicon controlled rectifier (SCR) comprises the p-doped anode 10, the n-well middle region 20′, the p-well middle region 30′, and the n-doped cathode 40, all of which are laid out along the surfaces of the portion S1 of the shallow trench isolation 50, specifically, along the set of surfaces containing the first sidewall 51, the bottom surface 53, and the second sidewall 52. The distance that an electrostatic discharge (ESD) current needs to flow through the SCR is substantially equivalent to the sum of the height of the first sidewall 51, the width w of the bottom surface 53, and the height of the second sidewall 52. The height of the first or second sidewall (51 or 52) is substantially the same as the depth of the shallow trench isolation 50, which is typically in the range from about 150 nm to about 400 nm, and may scale down with scaling of devices. The width w of the bottom surface 53 is in the range from about 100 nm and 300 nm, and may scale down with scaling of devices.

Optionally but preferably, the first exemplary semiconductor structure comprises a p-doped electrostatic discharge (ESD) implantation region 33 that abuts the heavily n-doped middle region 20″ and the p-well middle region 30′. For example, a top surface of the p-doped ESD implantation region 33 may abut the heavily n-doped middle region 20″ and side surfaces and a bottom surface of the p-doped ESD implantation region 33 may abut the p-well middle region 30′. The p-doped ESD implantation region 33 is disjoined from the n-well middle region 20′ and the n-doped cathode 40. The p-doped ESD implantation region 33 is optional, that is, the present invention may be practiced with, or without, the p-doped ESD implantation region 33.

The p-doped anode 10, the p-well middle region 30′, the p-doped middle region contact 31, and p-doped ESD implantation region 33 are doped with p-type dopants. The n-doped cathode 40, the n-well middle region 20′, and the heavily n-doped middle region 20″ are doped with n-type dopants. The dopant concentration of the p-doped anode 10, the n-doped cathode 40, and the p-doped middle region contact 31 may be in the range from about 1.0×10¹⁸/cm³ to about 5.0×10²¹/cm³, and typically in the range from about 5.0×10¹⁹/cm³ to about 5.0×10²⁰/cm³. The dopant concentration of the n-well middle region 20′ and the p-well middle region 30′ may be in the range from about 1.0×10¹⁶/cm³ to about 5.0×10¹⁹/cm³, and typically in the range from about 1.0×10¹⁷/cm³ to about 5.0×10¹⁸/cm³. The dopant concentration of the p-doped ESD implantation region 33 may be in the range from about 3.0×10¹⁶/cm³ to about 30×10²⁰/cm³, and typically in the range from about 3×10¹⁷/cm³ to about 3.0×10¹⁹/cm³.

The various views are also annotated with various geometrical features of the first exemplary structure. A p-doped ESD implantation region center X, or the center of the p-doped ESD implantation region 33, is herein defined as the geometric center of the volume of the p-doped ESD implantation region 33. The coordinate of the p-doped ESD implantation region center X is given by (X₁, X₂, X₃), wherein each Xᵢ is given by

$${X}_{i} = \frac{\int \int \int {x}_{i} d {x}_{1} d {x}_{2} d {x}_{3}}{\int \int \int d {x}_{1} d {x}_{2} d {x}_{3}} \qquad ( Equation 1 )$$

for i=1, 2, 3 and the volume integrals are defined over the volume of the p-doped ESD implantation region 33. Similarly, an n-doped cathode center Y, or the center of the n-doped cathode 40, is herein defined as the geometric center of the n-doped cathode 40; and a p-doped middle region contact center Z, or the center of the p-doped middle region contact 31, is herein defined as the geometric center of the p-doped middle region contact 31. The formula for the coordinates of Y and Z are given by

$$\begin{matrix}{Y}_{i} = \frac{\int \int \int {x}_{i} d {x}_{1} d {x}_{2} d {x}_{3}}{\int \int \int d {x}_{1} d {x}_{2} d {x}_{3}} , & ( Equation 2 ) \\ {Z}_{i} = \frac{\int \int \int {x}_{i} d {x}_{1} d {x}_{2} d {x}_{3}}{\int \int \int d {x}_{1} d {x}_{2} d {x}_{3}} , & ( Equation 3 )\end{matrix}$$

for i=1, 2, 3 and the volume integrals are defined over the volume of n-doped cathode 40 for Equation 2 and over the volume of the p-doped middle region contact 31 for Equation 3.

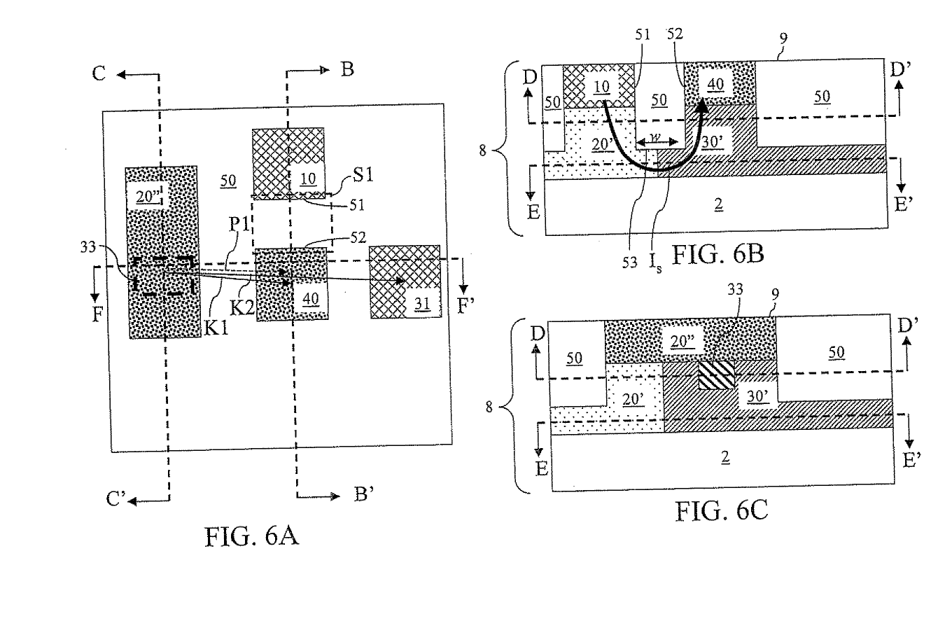

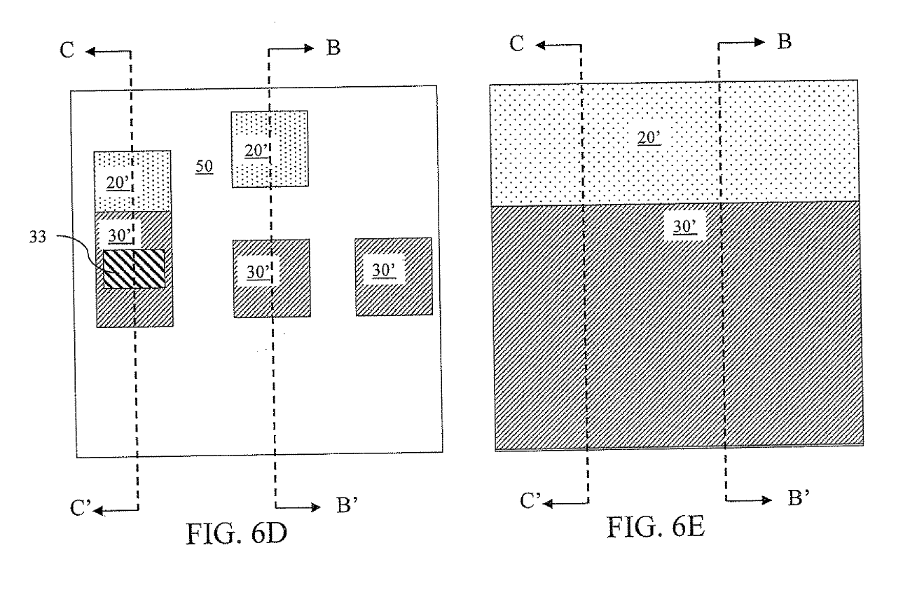

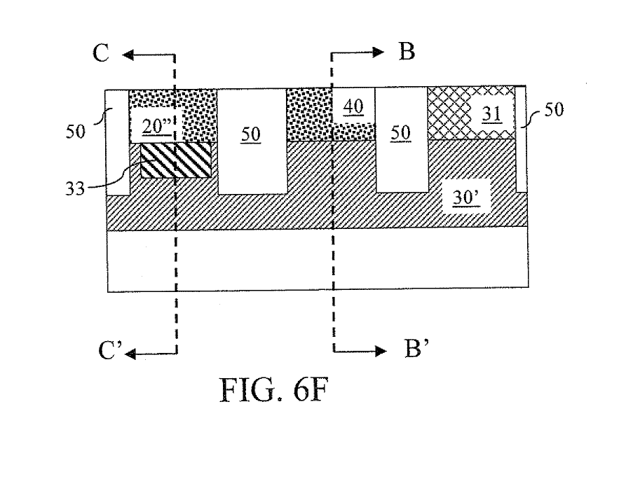

A first vector K1 herein connotes the vector from the p-doped ESD implantation region center X to the n-doped cathode center Y. A second vector K2 herein connotes the vector from the p-doped ESD implantation region center X to the p-doped middle region contact center Z. Since the vectors K1 and K2 are not located within any plane of the various cross-sections in FIGS. 6A-6E, their projections to the top surface 9 of the semiconductor substrate 8 are shown in FIG. 4A along with a projection of the p-doped ESD implantation region 33, which is marked with a dotted rectangle. The geometrical placement of the p-doped ESD implantation region 33, the n-doped cathode 40, and the p-doped middle region contact 31 in the first exemplary structure is such that the projection P of the first vector K1 onto the direction of the second vector K2 has the same direction as the second vector K2 and a smaller magnitude than the second vector K2. In other words, the p-doped middle region contact center Z is farther away than the n-doped cathode center Y from the p-doped ESD implantation region center X, and the angle between the two vectors K1 and K2 is less than 90 degrees.

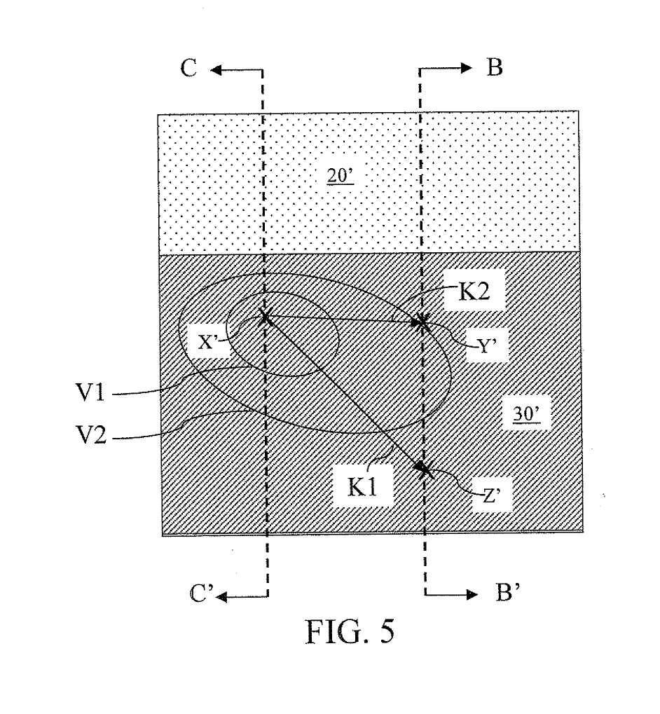

The benefit of such a geometrical placement of the components is seen in FIG. 5, which shows exemplary equipotential lines V1 and V2 at an initial phase of an ESD event in the same horizontal cross-sectional view as FIG. 4E. The projections of the points X, Y, and Z onto the plane of the cross-section of FIG. 5 are labeled points X′, Y′, and Z′, respectively. As an positive voltage is instantaneously applied to the heavily n-doped middle region 20″ either by a direct wiring to the source of the ESD event or through the p-doped anode 10, a reverse diode breakdown occurs between the heavily n-doped middle region 20″ and the p-doped ESD implantation region 33 since the p-doped ESD implantation region 33 is in general doped with a higher doping concentration than the p-well middle region 30′. If the p-doped ESD implantation region 33 is not present in the structure, the breakdown occurs between the heavily n-doped middle region 20″ and the p-well middle region 30′. An increase in the breakdown voltage, or a turn-on voltage of the SCR, may occur relative to a structure with the p-doped ESD implantation region 33.

Once a breakdown occurs between the heavily n-doped middle region 20″ and one of the -doped ESD implantation region 33 the p-well middle region 30′, an initial current flows from the n-well middle region 20′, optionally through the p-doped ESD implantation region 33, and to the p-well middle region 30′. Once the initial current flows into the p-well middle region 30′, another current path underneath the portion S1 of the shallow trench isolation 50 is established in the SCR. This is because the initial current serves as a base current that momentarily turns on a PNP bipolar transistor comprising the p-doped anode 10, the n-well middle region 20′, and the p-well middle region 30′.

As the initial current flows, equipotential lines such as V1 and V2 are instantaneously formed in the p-well middle region 30′ from the center of the current source, which is the p-doped ESD implantation region 33, during the initial phase of the ESD event. By placing the n-doped cathode center Y in closer proximity the p-doped ESD implantation region center X relative to the p-doped middle region contact center Z in FIGS. 4A-4E, the voltage at the point Y′ becomes high relative to the voltage at the n-doped anode center Y, which is maintained at ground potential.

Once current begins to flow between the p-well middle region 30′, and the n-doped cathode 40, another current path from the p-doped anode 10 through the n-well middle region 20′ to the p-well middle region 30′ is formed, conducting even more current. This is because the instantaneous voltage bias between the point Y′ and the n-doped anode center Y initiates the base current of an NPN transistor comprising the heavily n-doped middle region 20″, the p-well middle region 30′, and the n-doped cathode 40. Therefore, the silicon controlled rectifier (SCR) circuit comprising the p-doped anode 10, n-well middle region 20′, the p-well middle region 30′, and the n-doped cathode 40 is subsequently latched to an on-state. The steady state current IS of the SCR during the steady on-state is shown in FIG. 4B.

Referring to FIGS. 6A-6F, a second exemplary structure according to the first embodiment of the present invention is shown. In this example, the angle between the first vector K1 and the second vector K2 is minimized by placing the p-doped middle region contact 31 on the opposite side of the p-doped ESD implantation region 33 relative to the n-doped cathode 40. The angle between the first vector K1 and the second vector K2 is less than 45 degrees, and preferably less than 15 degrees. The smaller angle between the two vectors K1 and K2 has the advantageous effect of applying a higher voltage to the area of the p-well middle region 30′ directly beneath the n-doped cathode 40 (corresponding to the point X′ in FIG. 5) during the initial current flow, which lowers a trigger voltage for the turn-on of the SCR.

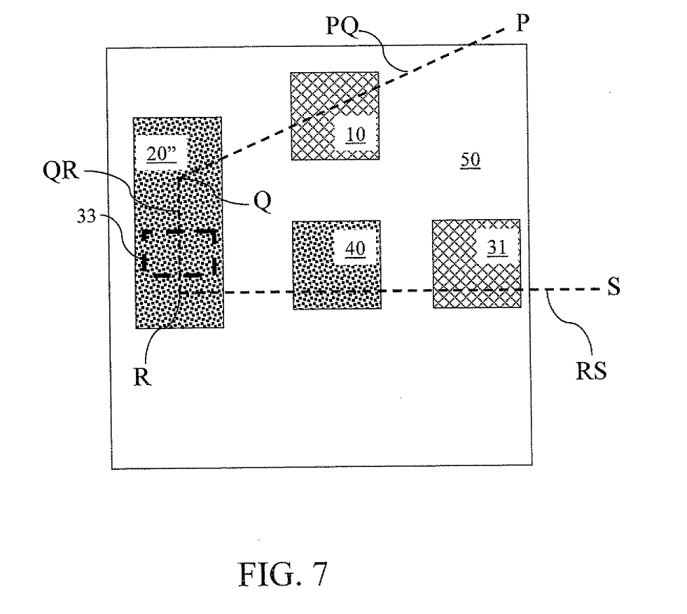

Referring to FIG. 7, a set of vertical planes that are formed by connecting the points P, Q, R, and S is shown in the same view as FIG. 6A. Plane PQ is a vertical plane bounded by the points P and Q; plane QR is the plane bounded by the points Q and R; and plane R and S is the plane bounded by the points R and S.

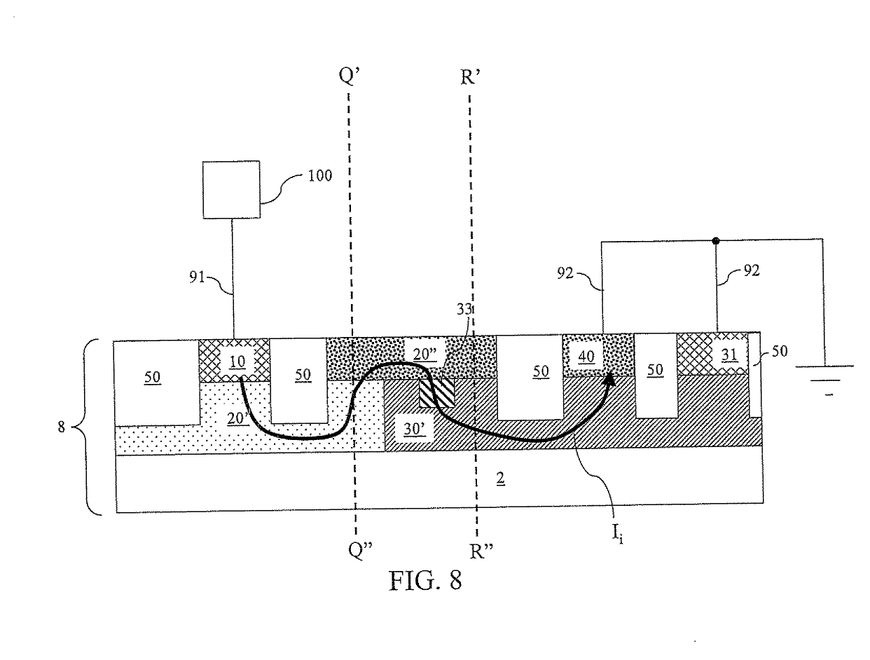

Referring to FIG. 8, a vertical cross-sectional view along a composite plane formed by juxtaposition of the planes PQ, QR, and RS of the second exemplary structure is shown with a schematic diagram for wiring of the components of the SCR. Pivot axes Q′−Q″ and R′−R″ of the cross-sectional view, respectively corresponding to the points Q and R in FIG. 7, are also shown. The p-doped anode 10 is wired to an input/output pad 100 by a first metal wiring 91. The input/output pad may be an input pad, an output pad, or a bidirectional pad and electrically connected to lead wires in a semiconductor package. The p-doped anode may also be connected to any internal circuitry that is vulnerable to electrostatic discharge. The n-doped cathode 40 and the p-doped middle region contact 31 are wired to ground by a second metal wiring 92. FIG. 8 also shows the path of an instantaneous current Iᵢ during a turn-on phase of the SCR. The steady state current Iₛ of the SCR during the steady on-state is as shown in FIGS. 4B and 6B.

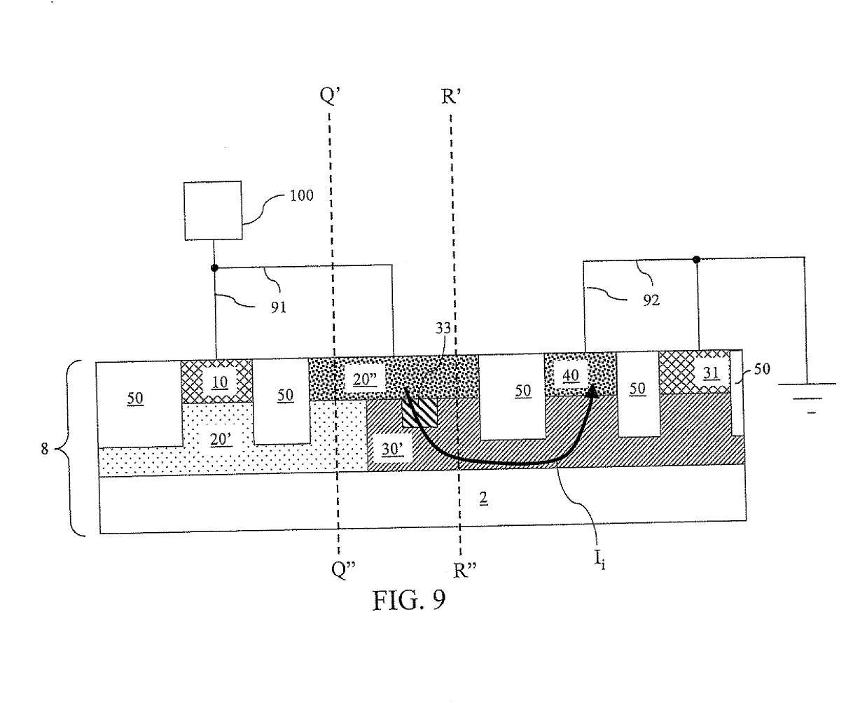

Referring to FIG. 9, a vertical cross-sectional view along the composite plane formed by juxtaposition of the planes PQ, QR, and RS of the second exemplary structure is shown with a schematic diagram for alternate wiring of the components of the SCR. Pivot axes Q′−Q″ and R′−-R″ of the cross-sectional view, respectively corresponding to the points Q and R in FIG. 7, are also shown. In addition to the wiring shown in FIG. 8, the heavily n-doped middle region 20″ is also wired to the input/output pad 100 by the first metal wiring 91. Due to a decrease in the voltage drop across the p-doped anode 10 and the heavily n-doped middle region 20″, the alternate wiring provides a lower turn-on voltage for the SCR relative to the wiring shown in FIG. 8. The n-doped cathode 40 and the p-doped middle region contact 31 are wired to ground by a second metal wiring 92. The path of an instantaneous current Iᵢ during a turn-on phase of the SCR is also shown.

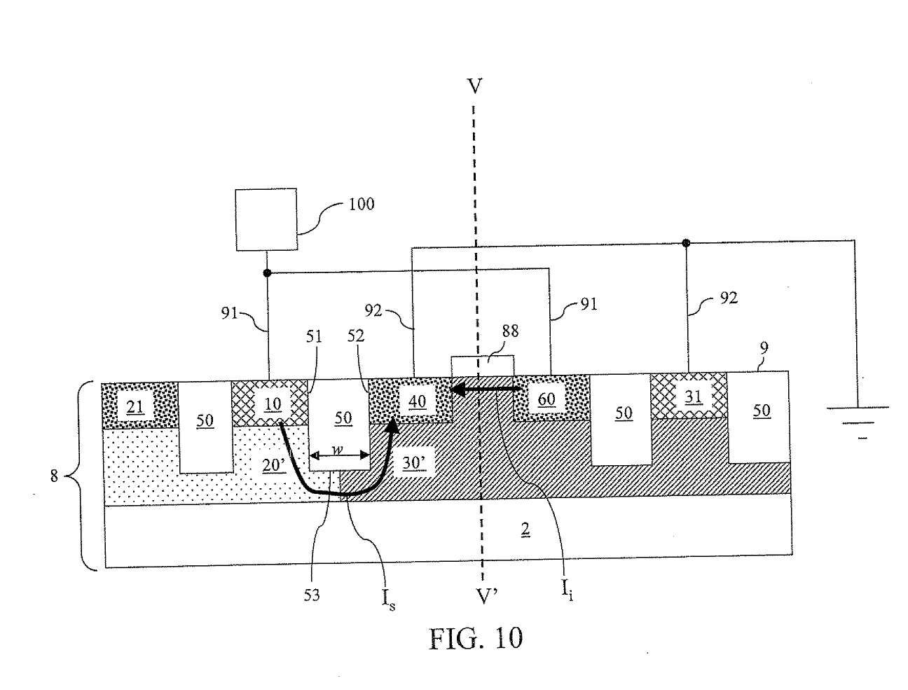

Referring to FIG. 10, a vertical cross-sectional view of a third exemplary structure according to a second embodiment of the present invention is shown. The vertical cross-sectional view may be from a single cross-sectional plane or may comprise two cross-sectional planes adjoined at a pivot axis V-V′. In other words, all components in the cross-sectional view may be arranged in a linear alignment or may be located on a set of two planes adjoined at a pivot axis V-V′.

Compared to the first exemplary structure, the third exemplary structure comprises all the components of the first exemplary structure except a heavily n-doped middle region 20″ and an optional p-doped electrostatic discharge (ESD) implantation region 33. The structural characteristics of the common components between the third exemplary structure and the first exemplary structure are the same. See above for descriptions of the common components between the third and first exemplary structures.

However, the third exemplary structure has an additional component, which is a heavily n-doped electrostatic discharge (ESD) trigger region 60 located within the semiconductor substrate 8, electrically connected to the p-well middle region 30′, and disjoined from the first sidewall 51, the second sidewall 52, the p-doped anode 10, the n-doped cathode 40, and the n-well middle region 20′. The heavily n-doped ESD trigger region 60 comprises a heavily n-doped semiconductor material, and has a doping concentration in the range from about 1.0×10¹⁸/cm³ to about 5.0×10²¹/cm³, and typically in the range from about 5.0×10¹⁹/cm³ to about 5.0×10²⁰/cm³, i.e., about the same level of doping concentration as the n-doped cathode 40. The p-doped anode 10 and the heavily n-doped ESD trigger region 60 are wired to an input/output pad 100 by a first metal wiring 91 and the n-doped cathode 40 is wired to ground by a second metal wiring 92. The p-doped middle region contact 31 contains a heavily p-doped semiconductor material and wired to ground by the second metal wiring 92. To prevent metallization of exposed portion of the p-well middle region 30′ between the heavily n-doped ESD trigger region 60 and the n-doped cathode 40, a patterned dielectric layer 88 comprising a dielectric material such as silicon nitride or silicon oxide may be formed and provide electrical isolation between the heavily n-doped ESD trigger region 60 and the n-doped cathode 40.

The heavily n-doped ESD trigger region 60 abuts the p-well middle region 30′. Also, the p-well middle region 50 abuts a top surface 9 of the semiconductor substrate 8 between the n-doped cathode 40 and the heavily n-doped ESD trigger region 60.

Preferably, the heavily n-doped ESD trigger region 60 is farther away from the p-doped anode 10 than the n-doped cathode 50 is from the p-doped anode 10. This is because the intended ESD current conduction path is through the SCR, i.e., through the p-doped anode 10, the n-well middle region 20′, the p-well middle region 30′, and the n-doped cathode 40. By keeping the p-doped anode 10 and the n-doped cathode 40 close together, the SCR remains a main current conduction path so that the characteristics of the ESD protection device maintain the electrical characteristics of the SCR. The direction of an instantaneous current Iᵢ during the turn-on phase of the SCR and the direction of a steady state current Iₛ during the steady on-state are indicated by labeled arrows.

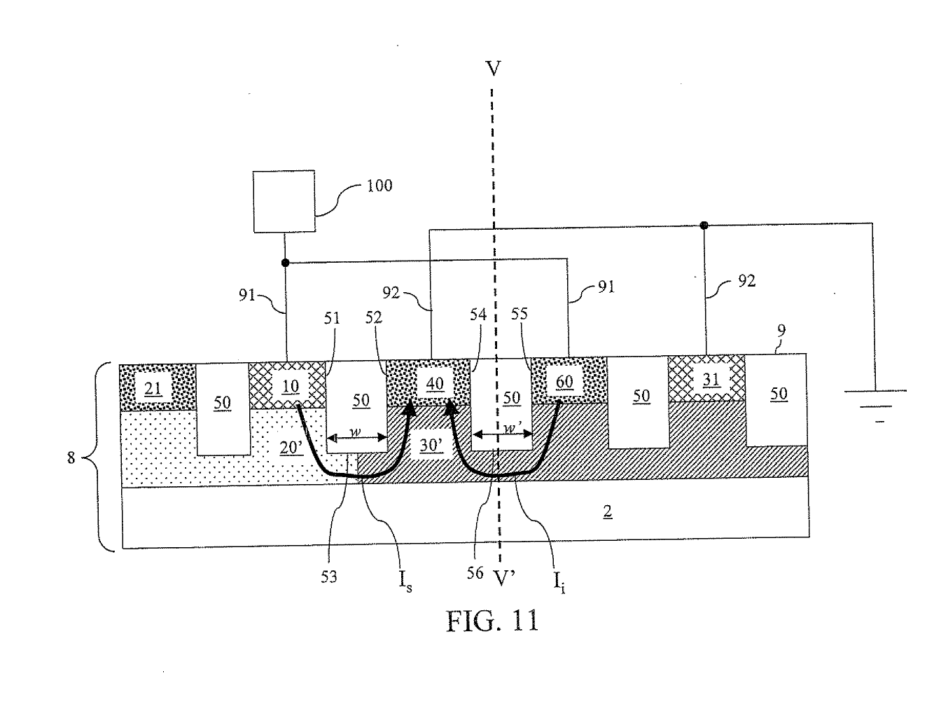

Referring to FIG. 11, a fourth exemplary structure according to the second embodiment of the present invention comprises all the components of the third exemplary structure above with the following modifications. The p-well middle region 50 does not abut a top surface 9 of the semiconductor substrate 8 between the n-doped cathode 40 and the heavily n-doped ESD trigger region 60. Instead, another portion of the shallow trench isolation 50 occupies the volume between the n-doped cathode 40 and the heavily n-doped ESD trigger region 60. The another portion of the shallow trench isolation 50 has another bottom surface 56 having another width w′, a third sidewall 54, and a fourth sidewall 55 and located in the semiconductor substrate 8. The another bottom surface 56 adjoins the third sidewall 54 and the fourth sidewall 55. The n-doped cathode 40 abuts the third sidewall 54, the heavily n-doped ESD trigger region 60 abuts the fourth sidewall 55, and the p-well middle region 30′ abuts the third sidewall 54, the fourth sidewall 55, and the another bottom surface 56. The n-doped cathode 40 and the heavily n-doped ESD trigger region 60 are separated by another distance that is substantially the same as the another width w′ of the another bottom surface 56.

Due to the presence of the another portion of the shallow trench isolation 50 in the fourth exemplary structure relative to the third exemplary structure, the fourth exemplary structure may have a higher turn-on voltage for the SCR. Preferably, the shortest distance between the heavily n-doped ESD trigger region 60 and the p-doped anode 10 is greater than the shortest distance between the n-doped cathode 40 and the p-doped anode 10. The direction of an instantaneous current Iᵢ during the turn-on phase of the SCR and the direction of a steady state current Iₛ during the steady on-state are indicated by labeled arrows.

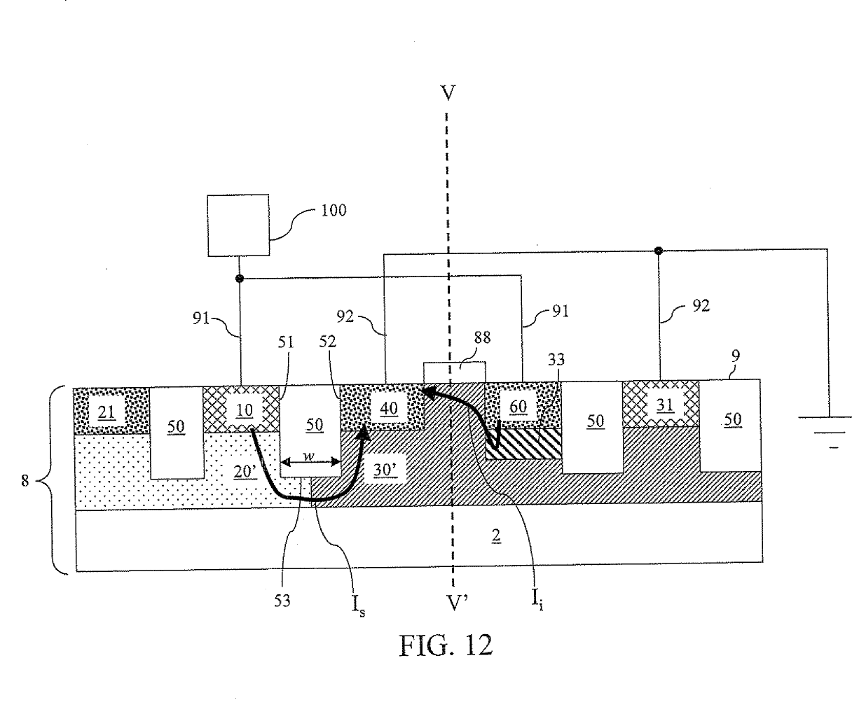

Referring to FIG. 12, a fifth exemplary structure according to the second embodiment of the present invention comprises all the components of the third exemplary structure above. The fifth exemplary structure further comprises a p-doped ESD implantation region 33 which abuts the heavily n-doped ESD trigger region 60 and the p-well middle region 30′. The p-doped ESD implantation region 33 in the fifth exemplary structure has the same doping as the p-doped ESD implantation region 33 in the first exemplary structure. The p-doped ESD implantation region 33 is disjoined from the n-well middle region 20′ and the n-doped cathode 40. The p-doped ESD implantation region 33 may, or may not, adjoin the shallow trench isolation 50. The direction of an instantaneous current Iᵢ during the turn-on phase of the SCR and the direction of a steady state current Iₛ during the steady on-state are indicated by labeled arrows. To prevent metallization of exposed portion of the p-well middle region 30′ between the heavily n-doped ESD trigger region 60 and the n-doped cathode 40, a patterned dielectric layer 88 comprising a dielectric material such as silicon nitride or silicon oxide may be formed and provide electrical isolation between the heavily n-doped ESD trigger region 60 and the n-doped cathode 40.

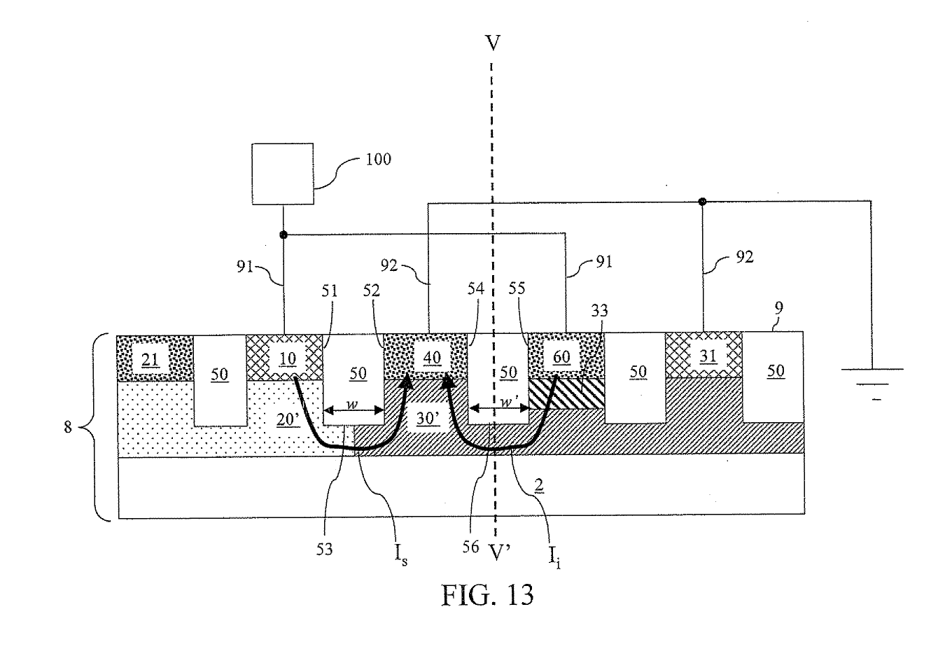

Referring to FIG. 13, a sixth exemplary structure according to the second embodiment of the present invention comprises all the components of the fourth exemplary structure above. The sixth exemplary structure further comprises a p-doped ESD implantation region 33 which abuts the heavily n-doped ESD trigger region 60 and the p-well middle region 30′. The p-doped ESD implantation region 33 in the fifth exemplary structure has the same doping as the p-doped ESD implantation region 33 in the first exemplary structure. The p-doped ESD implantation region 33 is disjoined from the n-well middle region 20′ and the n-doped cathode 40. The p-doped ESD implantation region 33 may, or may not, adjoin the shallow trench isolation 50. The direction of an instantaneous current Iᵢ during the turn-on phase of the SCR and the direction of a steady state current Iₛ during the steady on-state are indicated by labeled arrows.

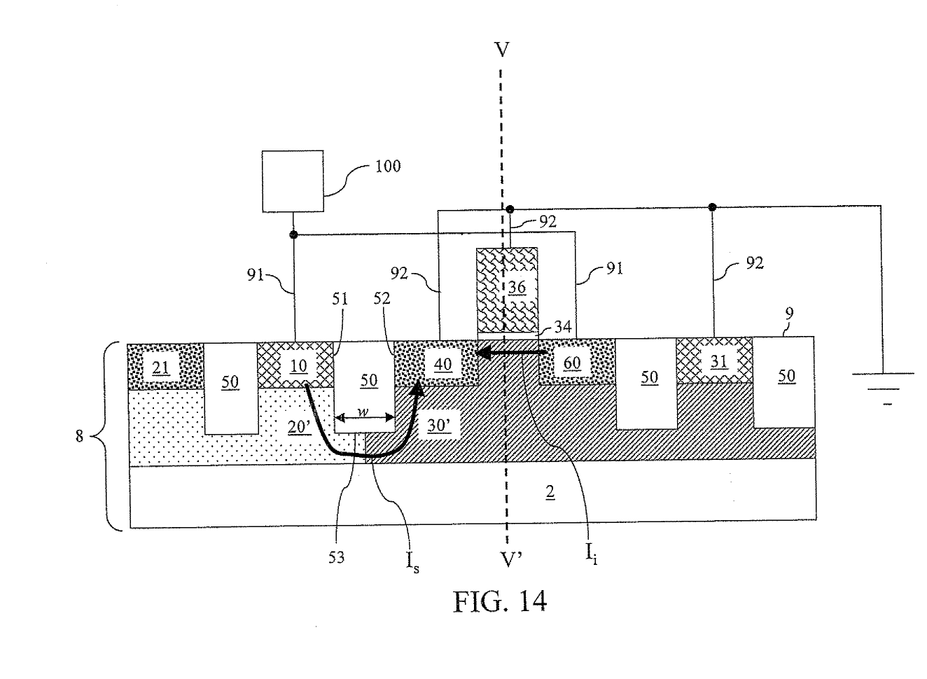

Referring to FIG. 14, a seventh exemplary structure according to a third embodiment of the present invention comprises all the components of the third exemplary structure above. The seventh exemplary structure further comprises a gate located on the top surface 9 of the semiconductor substrate 8, abutting p-well middle region 30′, and containing a gate dielectric 34 and a gate conductor 36. In other words, the seventh exemplary structure contains an n-type field effect transistor (NFET) in which p-well middle region 30′ functions as a body, the n-doped cathode 40 functions as a source, the heavily n-doped ESD trigger region 60 functions as a drain, and a gate is located between the n-doped cathode 40 and the heavily n-doped ESD trigger region 60. A threshold voltage adjustment implantation or a halo implantation may be performed into the p-well middle region 30′ to adjust the threshold voltage of the NFET.

The p-doped anode 40 and the heavily n-doped ESD trigger region 60 are wired to an input/output pad 100 by a first metal wiring 91. The n-doped cathode 40, the p-doped middle region contact 31, and the gate conductor 26 are wired to ground by a second metal wiring 92. The NFET is a grounded gate NFET (GGNFET) that provides an instantaneous current during the turn-on phase of the SCR, which comprises the p-doped anode 10, the n-well middle region 20′, the p-well middle region 30′, and the n-doped cathode 40. The direction of an instantaneous current Iᵢ during the turn-on phase of the SCR and the direction of a steady state current Iₛ during the steady on-state are indicated by labeled arrows.

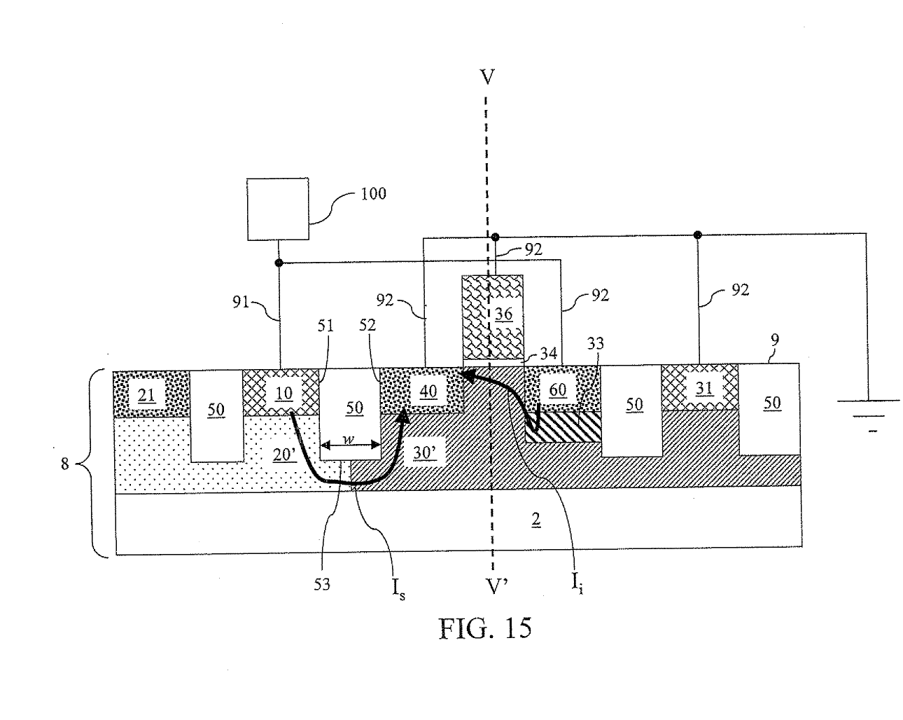

Referring to FIG. 15, an eighth exemplary structure according to the third embodiment of the present invention comprises all the components of the seventh exemplary structure above. The eighth exemplary structure further comprises a p-doped ESD implantation region 33 which abuts the heavily n-doped ESD trigger region 60 and the p-well middle region 30′. The p-doped ESD implantation region 33 in the eighth exemplary structure has the same doping as the p-doped ESD implantation region 33 in the first exemplary structure. Due to the higher doping concentration in the p-doped ESD implantation region 33 relative to the p-well middle region 30′, an instantaneous current during the turn-on phase of the SCR is initiated with a lower trigger voltage on the input/output pad 100 compared to the seventh exemplary structure. The gate is grounded as in the seventh exemplary structure. The direction of an instantaneous current Iᵢ during the turn-on phase of the SCR and the direction of a steady state current Iₛ during the steady on-state are indicated by labeled arrows.

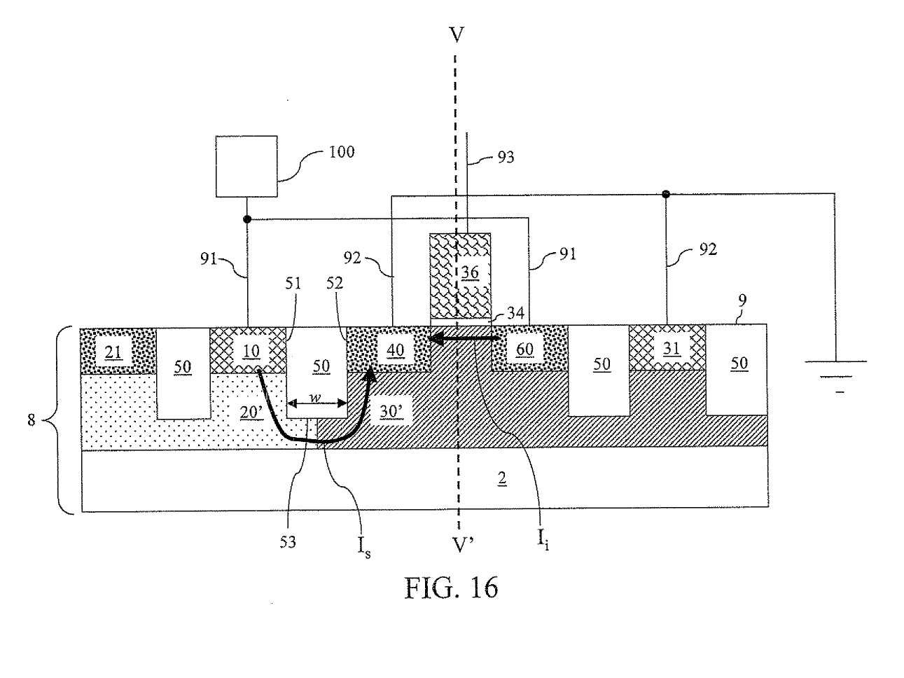

Referring to FIG. 16, a ninth exemplary structure according to the third embodiment of the present invention comprises all the elements of the seventh exemplary structure. However, the gate is not grounded. Instead, the gate is controlled independently to control the turn-on voltage of the SCR. The direction of an instantaneous current Iᵢ during the turn-on phase of the SCR and the direction of a steady state current Iₛ during the steady on-state are indicated by labeled arrows.

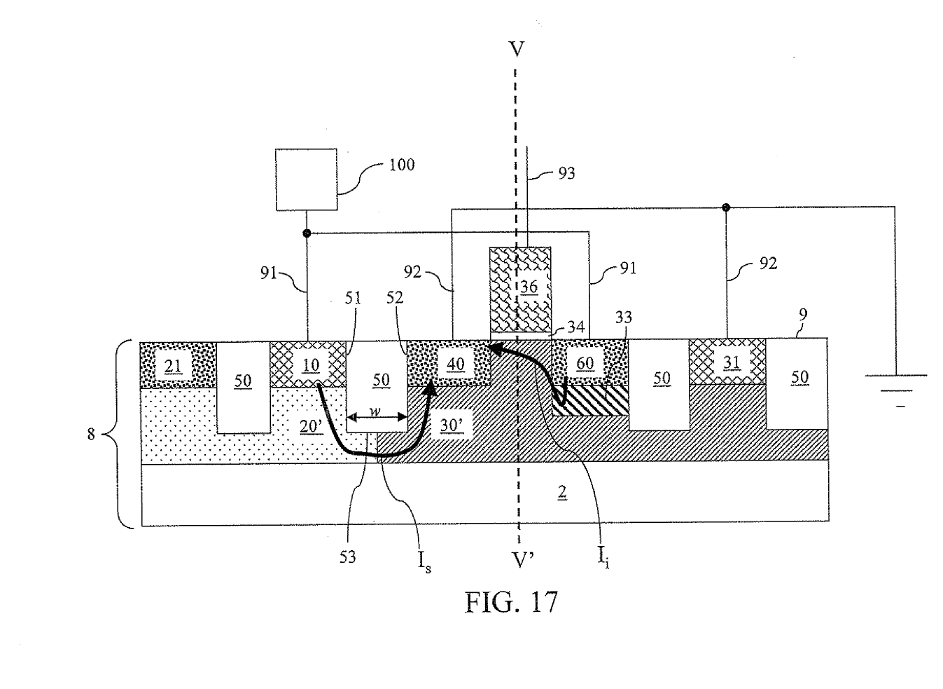

Referring to FIG. 17, a tenth exemplary structure according to the third embodiment of the present invention comprises all the elements of the eighth exemplary structure. As in the ninth exemplary structure, the gate is controlled independently to control the turn-on voltage of the SCR. The direction of an instantaneous current Iᵢ during the turn-on phase of the SCR and the direction of a steady state current Iₛ during the steady on-state are indicated by labeled arrows.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A semiconductor structure comprising:
a shallow trench isolation structure containing a bottom surface having a width, a first sidewall, and a second sidewall and located in a semiconductor substrate, wherein said bottom surface adjoins said first sidewall and said second sidewall;
a p-doped anode located directly beneath a top surface of said semiconductor substrate and abutting said first sidewall;
an n-well middle region abutting said p-doped anode, said first sidewall, and said bottom surface;
a p-well middle region abutting said n-well middle region, said bottom surface, and said second sidewall;
an n-doped cathode located directly beneath said top surface of said semiconductor substrate and abutting said p-well middle region and said second sidewall, wherein said p-doped anode and said n-doped cathode are separated by a distance that is substantially the same as said width of said bottom surface; and
a heavily n-doped middle region disjoined from said first sidewall, said second sidewall, said p-doped anode, and said n-doped cathode and abutting said n-well middle region and said p-well middle region, wherein said p-doped anode is wired to an input/output pad by a first metal wiring and said n-doped cathode is wired to ground by a second metal wiring.

2. The semiconductor structure of claim 1, further comprising a p-doped middle region contact containing a heavily p-doped semiconductor material and wired to said ground by said second metal wiring.

3. The semiconductor structure of claim 2, further comprising a p-doped electrostatic discharge (ESD) implantation region which abuts said heavily n-doped middle region and said p-well middle region and is disjoined from said n-well middle region and said n-doped cathode.

4. The semiconductor structure of claim 3, wherein the projection of a first vector from a center of said p-doped ESD implantation region to a center of said n-doped cathode onto a second vector from said center of said p-doped ESD implantation region to a center of said p-doped middle region contact has the same direction as said second vector and a smaller magnitude than said second vector.

5. The semiconductor structure of claim 2, wherein said heavily n-doped middle region is wired to said input/output pad by said first metal wiring.

6. A semiconductor structure comprising:
a shallow trench isolation structure containing a bottom surface having a width, a first sidewall, and a second sidewall and located in a semiconductor substrate, wherein said bottom surface adjoins said first sidewall and said second sidewall;
a p-doped anode located directly beneath a top surface of said semiconductor substrate and abutting said first sidewall;
an n-well middle region abutting said p-doped anode, said first sidewall, and said bottom surface;
a p-well middle region abutting said n-well middle region, said bottom surface, and said second sidewall;
an n-doped cathode located directly beneath said top surface of said semiconductor substrate and abutting said p-well middle region and said second sidewall, wherein said p-doped anode and said n-doped cathode are separated by a distance that is substantially the same as said width of said bottom surface; and
a heavily n-doped electrostatic discharge (ESD) trigger region located within said semiconductor substrate, electrically connected to said p-well middle region, and disjoined from said first sidewall, said second sidewall, said p-doped anode, said n-doped cathode, and said n-well middle region, wherein said p-doped anode and said heavily n-doped ESD trigger region are wired to an input/output pad by a first metal wiring and said n-doped cathode is wired to ground by a second metal wiring.

7. The semiconductor structure of claim 6, further comprising a p-doped middle region contact containing a heavily p-doped semiconductor material and wired to said ground by said second metal wiring.

8. The semiconductor structure of claim 7, wherein said heavily n-doped ESD trigger region abuts said p-well middle region.

9. The semiconductor structure of claim 8, wherein said p-well middle region abuts said top surface of said semiconductor substrate between said n-doped cathode and said heavily n-doped ESD trigger region.

10. The semiconductor structure of claim 8, further comprising another portion of said shallow trench isolation having another bottom surface having another width, a third sidewall, and a fourth sidewall and located in said semiconductor substrate, wherein said another bottom surface adjoins said third sidewall and said fourth sidewall, said n-doped cathode abuts said third sidewall, said heavily n-doped ESD trigger region abuts said fourth sidewall, said p-well middle region abuts said third sidewall, said fourth sidewall, and said another bottom surface, and said n-doped cathode and said heavily n-doped ESD trigger region are separated by another distance that is substantially the same as said another width of said another bottom surface.

11. The semiconductor structure of claim 8, wherein the shortest distance between said heavily n-doped ESD trigger region and said p-doped anode is greater than the shortest distance between said n-doped cathode and said p-doped anode.

12. The semiconductor structure of claim 7, further comprising a p-doped electrostatic discharge (ESD) implantation region which abuts said heavily n-doped ESD trigger region and said p-well middle region, and is disjoined from said n-well middle region and said n-doped cathode.

13. The semiconductor structure of claim 12, wherein said p-well middle region abuts said top surface of said semiconductor substrate between said n-doped cathode and said heavily n-doped ESD trigger region.

14. The semiconductor structure of claim 12, further comprising another portion of said shallow trench isolation having another bottom surface having another width, a third sidewall, and a fourth sidewall and located in said semiconductor substrate, wherein said another bottom surface adjoins said third sidewall and said fourth sidewall, said n-doped cathode abuts said third sidewall, said heavily n-doped ESD trigger region abuts said fourth sidewall, said p-well middle region abuts said third sidewall, said fourth sidewall, and said another bottom surface, and said n-doped cathode and said heavily n-doped ESD trigger region are separated by another distance that is substantially the same as said another width of said another bottom surface.

15. The semiconductor structure of claim 12, wherein the shortest distance between said heavily n-doped ESD trigger region and said p-doped anode is greater than the shortest distance between said n-doped cathode and said p-doped anode.

16. A semiconductor structure comprising:
a shallow trench isolation structure containing a bottom surface having a width, a first sidewall, and a second sidewall and located in a semiconductor substrate, wherein said bottom surface adjoins said first sidewall and said second sidewall;
a p-doped anode located directly beneath a top surface of said semiconductor substrate and abutting said first sidewall;
an n-well middle region abutting said p-doped anode, said first sidewall, and said bottom surface;
a p-well middle region abutting said n-well middle region, said bottom surface, said second sidewall, and said top surface of said semiconductor substrate;
an n-doped cathode located directly beneath said top surface of said semiconductor substrate and abutting said p-well middle region and said second sidewall, wherein said p-doped anode and said n-doped cathode are separated by a distance that is substantially the same as said width of said bottom surface;
a heavily n-doped electrostatic discharge (ESD) trigger region located within said semiconductor substrate, abutting said p-well middle region, and disjoined from said first sidewall, said second sidewall, said p-doped anode, said n-doped cathode, and said n-well middle region; and
a gate located on said top surface of said semiconductor substrate, abutting said p-well middle region, and containing a gate dielectric and a gate conductor, wherein said p-doped anode and said heavily n-doped ESD trigger region are wired to an input/output pad by a first metal wiring and said n-doped cathode is wired to ground by a second metal wiring.

17. The semiconductor structure of claim 16, further comprising a p-doped middle region contact containing a heavily p-doped semiconductor material and wired to said ground by said second metal wiring.

18. The semiconductor structure of claim 16, further comprising a p-doped electrostatic discharge (ESD) implantation region which abuts said heavily n-doped ESD trigger region and said p-well middle region, and is disjoined from said n-well middle region and said n-doped cathode.

19. The semiconductor structure of claim 16, wherein said gate is wired to said input/output pad by said first metal wiring.

20. The semiconductor structure of claim 16, wherein the shortest distance between said heavily n-doped ESD trigger region and said p-doped anode is greater than the shortest distance between said n-doped cathode and said p-doped anode.
